(19) United States
(12) Patent Application Publication
(10) Pub. No.: US 2017/0310196 A1
(43) Pub. Date: Oct. 26, 2017

(54) POWER GENERATION DEVICE FOR A VEHICLE

(71) Applicant: WEIDPLAS GMBH, Küsnacht (CH)

(72) Inventors: Sascha BUEHRLE, Palo Alto, CA (US); Urs BODMER, Xiamen (CN)

(73) Assignee: WEIDPLAS GMBH, Küsnacht (CH)

(21) Appl. No.: 15/532,337

(22) PCT Filed: Nov. 26, 2015
(86) PCT No.: PCT/EP2015/077793

§ 371 Date: Jul. 7, 2017

(30) Foreign Application Priority Data
Dec. 2, 2014 (EP) 14195843.9

(51) Int. Cl. H02K 7/18; H01L 41/113; H02N 1/08; H02K 35/04; B60G 17/019; B60Q 1/32

(52) U.S. Cl. CPC H02K 7/1892; H02N 1/08; H02K 35/04; H01L 41/113; B60Q 1/323; B60G 17/01908

(57) ABSTRACT

Disclosed is a power-generating backlit trim strip for a vehicle, comprising an oscillation system (3, 4; 3, 14), an induction unit (2), a sensor (17) and a control unit (8). The oscillation system (3, 4; 3, 14) includes a movably arranged gyrating mass (3), and the induction unit (2) is used for inductively converting kinetic energy of the gyrating mass (3) into electricity. The sensor (17) is used for determining a frequency of the vehicle vibrations, and the control unit (8) is used for adjusting the resonant frequency of the oscillation system (3, 4; 3, 14) to a determined frequency of the vehicle vibrations.

### TECHNICAL FIELD

The present invention relates to an electric power generating device for a vehicle. The device may be a backlightable trim strip, such as, for example, and entry strip. The invention additionally relates to a vehicle having such a device, and to a method for generating electrical energy in a vehicle.

### PRIOR ART

In vehicles, and particularly in the field of automobiles, it is frequently the case that a multiplicity of different electrically operated devices are used, such as, for example, a car radio, a hands-free car kit, an air-conditioning system, etc. These devices usually draw the energy required for their operation from the vehicle's electrical system, which usually has an energy storage in the form of a storage battery, which is itself charged by the engine during travel.

Besides these devices that have a relatively high energy demand, ever more frequently in vehicles electrically operated devices are used that have a comparatively low demand for electrical energy. Such a device may be, for example, a backlightable trim strip, which may be disposed, for example, as an entry strip, directly beneath the vehicle doors, for example to display the make of the automobile or a warning message to the driver as the latter enters the vehicle. Usually, in the case of such trim strips, the amount of energy required for backlighting is very small.

Even if the energy demand is low in the case of such electrically operated devices, it is usually necessary to provide elaborate cabling in order to connect the device to the electrical system of the vehicle. Frequently, additional connecting cables have to be laid in the vehicle, and it is necessary to make additional drilled holes in the vehicle body for routing through this connecting cable. It is precisely in the case of trim strips, and particularly in the case of entry strips, that there is a risk of ingress of moisture into the vehicle in the region of a drilled hole through which the connecting cable is routed. Moreover, the electrical devices, and particularly entry strips, are frequently exposed to external mechanical influences that may result in the connecting cable connected thereto becoming kinked or pinched, particularly if it is routed through a drilled hole in the body. In addition, owing to the elaborate cabling, retrofitting vehicles with such electrically operated devices is costly.

As an alternative to connection to the vehicle's electrical system, batteries, or rechargeable storage batteries, are often used in vehicle electrical devices. The disadvantage of batteries, or storage batteries, is that they have to be replaced, or recharged, after a certain period of time, which means an certain amount of effort on the part of the user. In addition, the batteries, or storage batteries, are subject to temperature fluctuations, as a result of which their functioning and service life cannot be adequately assured, depending on the particular application and type of application.

An entry strip for a vehicle, which is operated by batteries in the form of button cells, is disclosed in DE 10 2011 112 808 A1.

US 2007/0258262 A1 and U.S. Pat. No. 5,578,877 each propose an autonomous energy supply system for an electrical apparatus in a vehicle. These systems are each based on an oscillation system, having a movably disposed inertial mass, and having an induction unit for inductively converting kinetic energy of the inertial mass into electrical energy. The inertial mass is put into motion by the vibrations produced when the vehicle is in operation, and generates electric power for the respective electrical apparatus. However, depending on the vehicle type, charge state, road surface, etc., the energy yield of such autonomous energy supply system is frequently unsatisfactory.

### SUMMARY OF THE INVENTION

It is thus an object of the present invention to improve the energy yield in the case of an electric power generating device for a vehicle. In addition, the electric power generating device is to be as easy to use as possible, and such that it can be used in differing vehicles and vehicle types. To achieve this object, there is proposed an electric power generating device as specified in claim 1. In addition, a vehicle having such an electric power generating device is specified in claim 13. Advantageous embodiments of the invention are specified in the dependent claims.

The present invention thus provides an electric power generating device for a vehicle, in particular a motor vehicle, having
an oscillation system having a movably disposed inertial mass; and
an induction unit for inductively converting kinetic energy of the inertial mass into electrical energy.
   The electric power generating device additionally has at least one sensor, in particular an acceleration sensor, for determining an oscillation frequency of the vehicle, and a control unit for adjusting the resonant frequency of the oscillation system to a determined oscillation frequency of the vehicle.

The electric power generating device is a backlightable trim strip. The backlightable trim strip is, for example, an interior strip such as, for example, an entry strip or an exterior strip. An exterior strip, in the case of vehicles comprising a door, is a strip that is visible from outside of the vehicle when the door is closed. The electric power generating device is preferably fastened to a non-movable component of the vehicle, such as, for example, the body. The entry strip is preferably fastened to a door threshold, but may also be fastened in the region of the trunk. The oscillation system, the induction unit and the sensor, and at least one lighting element such as, in particular an LED, are preferably disposed in an interior of the trim strip. Thus, in this case, the electric current generated in the device is used for autonomously supplying energy to the device, and in particular to the lighting element. Preferably, the interior is covered outwardly by a cover that is translucent to the lighting element and that, for this purpose, preferably has backlightable through-holes. In particular, a light guide, advantageously realized as a diffusor, may be disposed between the lighting element and the through-holes, in order to direct the light, emitted by the lighting element, to the cover, in particular to the through-holes in the cover. Preferably, the trim strip, in particular the entry strip, has a thickness of 5 millimeters or less. The electric power generating device may have a light sensor, in order to detect the opening state of a vehicle door and to switch the lighting element on or off in dependence on the detected opening state of the vehicle door.

By means of the sensor, the control unit can, when required, determine an oscillation frequency of the vehicle and accordingly adjust the resonant frequency of the oscillation system to a determined oscillation frequency. The control unit, using data recorded by the sensor, thus determines at least one oscillation frequency of the vehicle. From the at least one determined oscillation frequency, at least one frequency is selected, and the frequency of the oscillation system, in particular of the inertial mass, is brought into resonance with the selected frequency. Within the scope of the invention, the frequency of the oscillation system, in particular of the inertial mass, that is brought into resonance with the selected frequency is referred to as the resonant frequency. In this way, it can be ensured that the oscillation system is optimally adjusted to the current conditions, i.e. is optimally adjusted to the currently prevailing vibrations of the vehicle, which are dependent, for example, on the vehicle type, the tires, the charge state or the road state (snow, asphalt, gravel path, etc.). Since the oscillation system can be brought at any time into resonance with the vibrations of the vehicle, the vibrations of the vehicle are optimally converted into an oscillation motion of the inertial mass, and consequently the kinetic energy of the oscillating inertial mass is converted, by means of induction, into electrical energy. Owing to this preferably automatic adjustment of the resonant frequency to an oscillation frequency of the vehicle, the same electric power generating device can thus be used, without further provisions, in a great variety of vehicles. The electric power generating device can thus be produced in an identical manner for differing vehicles, thereby reducing the resource requirement and production costs. In addition, the device is particularly well suited for retrofitting, since it is generally not necessary for manual adaptations of the oscillation system to be made for mounting on the vehicle. Owing to the structure of the oscillation system of the device according to the invention, the electric power generating device can be of a comparatively slim design, and therefore take up comparatively little structural space in the vehicle.

For the purpose of determining an oscillation frequency of the vehicle, at least one frequency spectrum of the data determined by the sensor, in particular acceleration data, can be calculated in the control unit, and a frequency selected, from the at least one frequency spectrum, that preferably allows a maximum energy yield. The energy yield is dependent, in particular, on the level of the frequency and on the amplitude of the vibration. The oscillation system can accordingly be set by the control unit in such a manner that the resonant frequency is adjusted to the frequency selected from the at least one frequency spectrum, such that the electric power generating device preferably can take up a maximum amount of energy. The control unit is usually an electronic device that advantageously has a computing unit such as, in particular, a CPU.

The electric power generating device advantageously has at least two oscillation systems, each having an inertial mass and an induction unit. The oscillation systems can then, with their resonant frequencies, be adjusted, for example, to differing typically occurring vibration frequencies of the vehicle. The oscillation systems may be realized in such a manner that their inertial masses can be moved in respectively the same direction. However, the oscillation systems may also be realized in such a manner that their inertial masses can be moved in differing directions, in particular in mutually substantially perpendicular directions. The fact that the at least two oscillation systems are realized in such a manner that their inertial masses can be moved in differing directions offers the advantage that the vibrations of the vehicle can be converted, irrespective of their direction, into a motion of at least one inertial mass, and consequently into electrical energy.

The vehicle may be, in particular, a road vehicle, such as an automobile, a lorry or a motorcycle. However, it may also be a rail-bound vehicle or an aircraft.

Advantageously, the sensor is disposed in or directly on the electric power generating device, more advantageously in the electric power generating device. The fact that the sensor is disposed in or directly on the electric power generating device offers the advantage that the vibrations of the vehicle that are transmitted to the electric power generating device, in particular to the oscillation unit thereof, and that therefore can potentially be converted into electrical energy by the oscillation system, can also be detected by the sensor. The sensor therefore directly detects the vibrations of the vehicle that are taken up by the electric power generating device and that potentially can be converted into electrical energy, such that the control unit can adjust the resonant frequency of the oscillation system, or of its inertial mass, to the frequencies of the vibrations of the vehicle that can be converted into electrical energy. The manner in which, or how or how firmly, the electric power generating device is fastened to the vehicle is therefore not so critical. Clearly, the sensor may also be disposed outside of the electric power generating device, in or directly on the vehicle, and for example wirelessly transmit the determined frequency data of the vibrations of the vehicle to the electric power generating device. In this case, the sensor is operated by the vehicle's electrical system.

The sensor is preferably an acceleration sensor. For this application, suitable acceleration sensors have long been known to the person skilled in the art. The use of one or more vibration plates in the sensor is likewise possible.

The inertial mass, which advantageously has a permanent magnet, is usually disposed in such a manner that it can be displaced or rotated, for example, relative to a neutral position. In the case of displacement, the inertial mass preferably executes a translational motion, more preferably a linear motion. The oscillation system usually has at least one restoring element, in order to exert a restoring force on the inertial mass, in the direction of the neutral position, in the case of a movement of the inertial mass out of its neutral position.

Advantageously, the resonant frequency is selected at least to a frequency from the frequency spectrum of the vibrations of the vehicle in the x direction, the x direction being defined as the direction coaxial to the longitudinal axis of the vehicle, the y axis being defined as the direction at an angle of 90° transverse to the x axis, and the z axis being defined as the direction at an angle of 90° in relation to the x axis and in relation to the y axis. The frequency spectrum of the vibrations of the vehicle in the x direction is preferably determined by means of an acceleration sensor. In the case of vehicles, in particular automobiles, the vibrations in the x direction have comparatively particularly high frequencies and amplitudes, and consequently the adjustment of the resonant frequency to a frequency in the x direction results in a particularly high energy yield by the electric power generating device. A particularly high energy yield is obtained, in particular, if the electric power generating device, in particular its inertial mass, is disposed parallel to, or coaxially with, the longitudinal axis of the vehicle, in particular of an automobile. Clearly, the resonant frequency can be adjusted to a frequency that occurs in the frequency spectrum of the vibrations of the vehicle in the x direction and in the frequency spectrum of the vibrations of the vehicle in the y direction and/or z direction. If, in addition to the frequency spectrum in the x direction, the frequency spectrum in the y direction and/or z direction is taken into account, the electric power generating device preferably has an oscillation system, in particular an inertial mass, that can oscillate in the additional direction(s) to be taken into account.

Advantageously, two restoring elements are provided, between which the inertial mass can be moved back and forth in an oscillating motion. A spring, for example, such as, in particular, a helical spring or torsion spring, may serve as a restoring element, in order, upon the inertial mass moving out of its neutral position, to exert a restoring force on the inertial mass, in the direction of the neutral position. The restoring force is then at least partly, in particular substantially entirely, a spring force. Also possible, however, is the use of one or more magnets in order, upon the inertial mass moving out of its neutral position, to exert, as a restoring element or restoring elements, a restoring force on the inertial mass, in the direction of the neutral position. The magnet or magnets may be realized as permanent magnets or electromagnets. The restoring force is then at least partly, in particular substantially entirely, a magnetic force.

Preferably, the induction unit has at least one induction coil having a multiplicity of windings. A motion of the inertial mass generates an electric current as a result of electromagnetic induction in the induction coil, for which reason the device is suitable for autonomous energy supply. The induction coil is advantageously disposed in such a manner that it at least partly surrounds the inertial mass when the latter executes a oscillation motion. Preferably, at least one winding of the induction coil can be switched into and out of circuit for the purpose of adjusting the resonant frequency of the oscillation system. The individual windings can thus each preferably be switched into and out of circuit individually. In this way, on the basis of Lenz's law, particularly simple adjustment of the resonant frequency by means of the control unit is possible. Alternatively, the resonant frequency of the oscillation system could also be adjusted, for example, in that the restoring elements are displaced in respect of their position relative to the inertial mass, or in that the restoring force acting on the inertial mass is altered, this being particularly simple if an electromagnet is used as a restoring element.

The electric power generating device is advantageously of an overall compact design, and preferably has a housing, having an interior within which the oscillation system, the induction unit and the sensor are disposed. Advantageously, the housing is substantially completely closed outwardly, such that the interior is not readily accessible from the outside.

Advantageously, the resonant frequency of the oscillation system is in the range of from 15 to 80 Hz, in particular in the range of from 25 to 45 Hz. The oscillation system is thus matched to the frequencies of the vibrations that usually occur in vehicles, particularly automobiles. Preferably, the resonant frequency of the oscillation system can be set, within this range, to the actually occurring oscillation frequency. In the case of vehicles, in particular in the case of automobiles, when the engines thereof are in operation during standstill or during travel, the vibration frequencies vary usually in a range of from 15 to 80 Hz, in particular 25 to 45 Hz. These vibration frequencies of the vehicle, in particular automobile, are preferably measured by means of an acceleration sensor.

In addition, the electric power generating device advantageously has an energy storage for storing the electrical energy generated by the induction unit. The energy generated during the travel of the vehicle can thus still be available even after stoppage of the vehicle. The energy storage may be a rechargeable storage battery. Advantageously, however, a capacitor storage is used as an energy storage, since it is less influenced by temperature fluctuations. Moreover, if a capacitor storage is used, charging electronics are not absolutely necessary. The use of an ultracapacitor has proved to be particularly advantageous, since the generated electrical energy then remains stored for up to two weeks, which is normally adequate for most applications, and in particular for the backlighting of trim strips. The capacitor storage can be accommodated in a particularly space-saving manner if it is of a flat design.

The present invention additionally relates to a vehicle having an electric power generating device realized as specified. The connection of the vehicle and the electric power generating device, or the fastening of the electric power generating device to the vehicle, is preferably such that the vibrations can be optimally transmitted to the oscillation system of the electric power generating device. To enable the vibrations occurring in the vehicle to be taken up in an optimal manner, the electric power generating device is advantageously fixedly connected to the body of the vehicle, i.e. fixed to the substructure of the vehicle. The electric power generating device is advantageously fastened to the vehicle body via a vehicle element, i.e. indirectly fastened to the vehicle body, or advantageously indirectly fastened to the vehicle body.

The oscillation system, in particular with regard to the direction of motion of the inertial mass when in the oscillating state, is disposed substantially parallel to, preferably coaxially with, the longitudinal axis of the vehicle. The oscillation system, in particular the inertial mass thereof, therefore preferably oscillates substantially parallel to, preferably coaxially with, the longitudinal axis of the vehicle, and thus in the direction of travel of the vehicle. This offers the advantage that the energy yield of the electric power generating device is particularly high in the case of vehicles, in particular in the case of automobiles.

The electric power generating device may be attached to the vehicle, for example, by means of screws or by means of an adhesive such as, in particular, a double-sided adhesive tape. However, the device may also have one or more magnets for magnetically fastening the device to the vehicle.

### BRIEF DESCRIPTION OF THE DRAWINGS

Preferred embodiments of the invention are described in the following on the basis of the drawings, which serve merely for explanation and which are not to be construed as limiting. There are shown in the drawings:

FIG. 1 a sectional view through a partially represented first embodiment of a device according to the invention in the form of a backlightable trim strip, having vertical and horizontal spring-mass oscillation systems;

FIG. 2 a sectional view through a partially represented second embodiment of a device according to the invention in the form of a backlightable trim strip, having two spring-mass oscillation systems, which are disposed on one side;

FIG. 3 a sectional view through a partially represented third embodiment of a device according to the invention in the form of a backlightable trim strip, having two spring-mass oscillation systems, which are disposed on both sides;

FIG. 4 a sectional view through a partially represented fourth embodiment of a device according to the invention in the form of a backlightable trim strip, having two magnet-magnet oscillation systems, which are disposed on both sides;

FIG. 5 a sectional view through a partially represented fifth embodiment of a device according to the invention in the form of a backlightable trim strip, having two magnet-magnet oscillation system, which are disposed on one side;

FIG. 6 a sectional view through a partially represented sixth embodiment of a device according to the invention in the form of a backlightable trim strip, having two rotatory oscillation systems, which are disposed on both sides;

FIG. 7 a schematic illustration of the x, y and z axis of a vehicle;

FIG. 8a the x component of the data determined by the acceleration sensor;

FIG. 8b the y component of the data determined by the acceleration sensor;

FIG. 8c the z component of the data determined by the acceleration sensor;

FIG. 9a the frequency spectrum of the data shown in FIG. 8a;

FIG. 9b the frequency spectrum of the data shown in FIG. 8b; and

FIG. 9c the frequency spectrum of the data shown in FIG. 8c.

### DESCRIPTION OF PREFERRED EMBODIMENTS

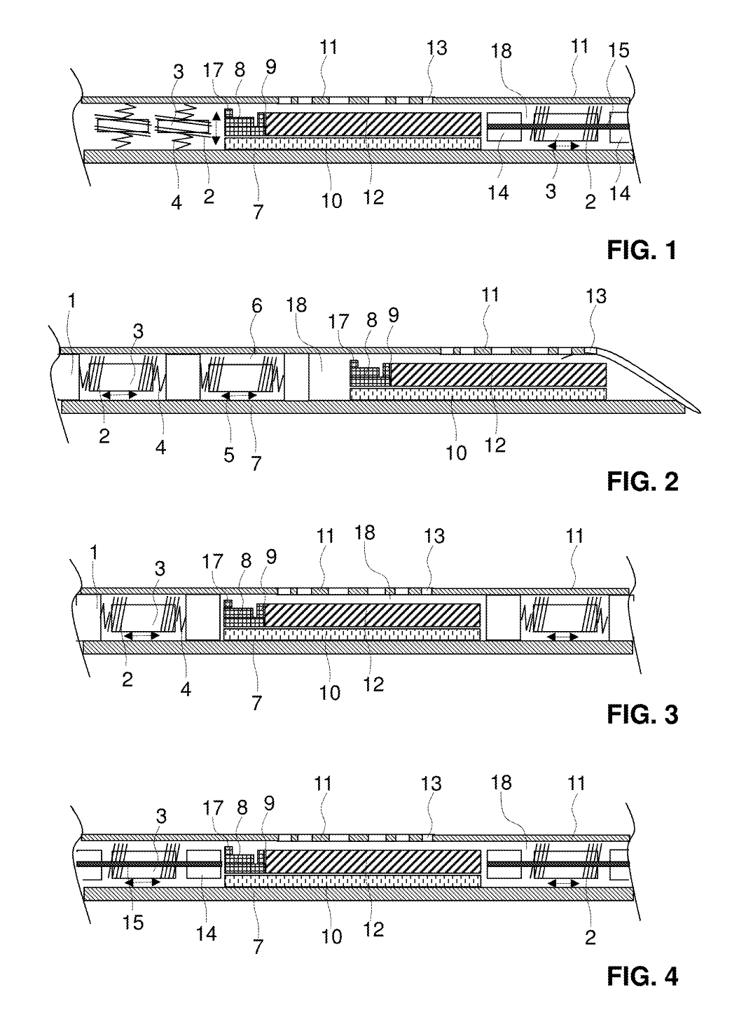

FIGS. 1 to 6 show differing embodiments of electric power generating devices according to the invention for a vehicle. All of the devices shown in FIGS. 1 to 6 are trim strips that, preferably, are disposed as an entry strip in the foot region of one of the vehicle doors. The trim strips may, however, be disposed at any other location inside or on the outside of the vehicle, such as, for example, in the region of the trunk door or the dashboard. Preferably, the trim strips have a longitudinal direction, defined by the maximum longitudinal extent of the trim strip, that extends parallel to the longitudinal axis 20 of the vehicle. Advantageously, the trim strip is fixedly connected to the vehicle body. In particular, it may be stuck onto a vehicle element that is fixedly connected to the vehicle body, or fastened by means of magnets, i.e. indirectly fastened to the vehicle body, or directly fastened to the vehicle body.

In respect of the embodiments shown in FIGS. 1 to 6, respectively the same references are used for elements that are the same or similar, or that are the same or similar in their effect.

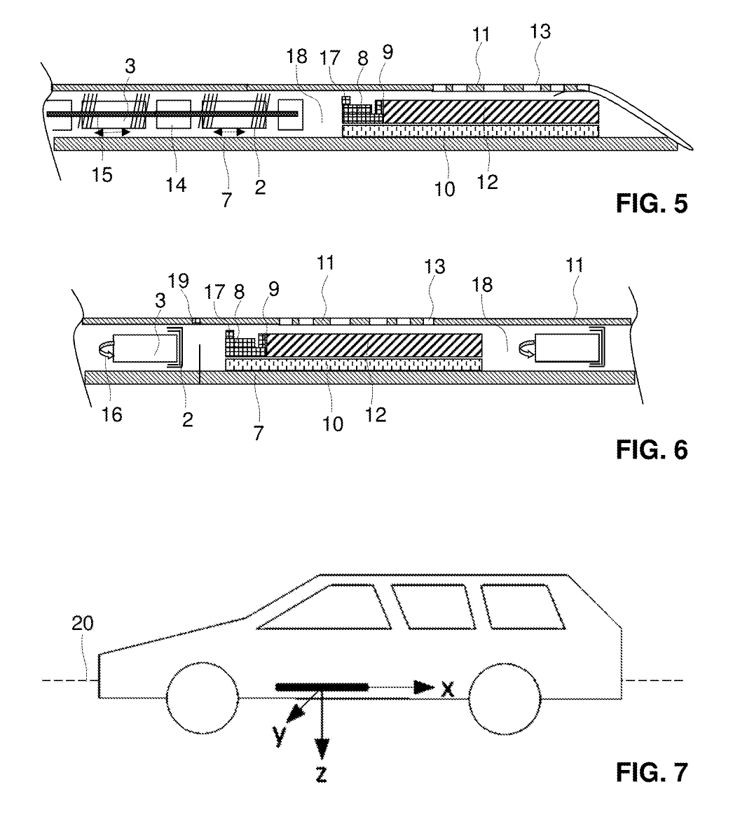

The trim strip shown in FIG. 1 has a housing having an interior 18. The interior 18 is delimited outwardly by a flat cover 11 and a support plate 7, which constitute a part of the housing. Whereas the cover 11, with its side that faces away from the interior 18, forms the visible side of the trim strip, the support plate 7, with its side that faces away from the interior 18, forms the back side of the trim strip. The cover 11 delimits the interior 18, not only forward, toward the visible side, but also all the way around laterally (shown partially in FIGS. 2 and 5).

Provided within the cover 11 are through-holes 13 that each form an opening, in order for light, emitted by a lighting element 9 disposed in the interior, to be passed through to the outside. The through-holes 13, because of their outer shape, may form, for example, letters, logotypes, symbols or similar. In order to prevent the ingress of moisture and dirt particles into the interior 18, the through-holes 13 are each closed with a translucent material such as, for example, polymethyl methylacrylate (PMMA).

Disposed directly behind the through-holes 13, in the interior 18, is a plate-type light guide 12, which serves to direct light, emitted by the lighting element 9, toward the through-holes 13. The light guide 12 may be designed, in particular, as a diffusor, such that the through-holes 13 can be uniformly backlit by the light that is emitted by a single lighting element 9. The lighting element 9 is preferably one or more LEDs, disposed at the side of the light guide 12. The lighting element 9 and the light guide 12 are disposed substantially at the same level between the cover 11 and the support plate 7. The trim strip is consequently of minimal height.

Disposed laterally in relation to the light guide 12, in the interior 18, are a plurality of oscillation systems and induction units. The oscillation systems each have an inertial mass, in the form of a magnet 3, disposed in a movable manner in the interior 18, and a restoring element in the form of springs 4 or fixed magnets 14. In the case of an excursion of the magnet 3 out of its neutral position, the restoring elements serve to exert a restoring force on the magnet 3, in the direction of its neutral position. The strength of the restoring force is proportional to the excursion of the magnet 3 out of its neutral position. In the case of an external action of force on the oscillation system, such as, in particular, in the case of a vibration caused by the vehicle, the magnet 3 is deflected out of its neutral position, in each case due to inertia, and, because of the restoring elements, goes into an oscillation motion.

Disposed next to each other, on the left side of the light guide 12, in the view of FIG. 2, are two oscillation systems, each having a movable magnet 3 and corresponding restoring elements for holding the magnet. In the case of both oscillation systems, the restoring elements in each case are two springs 4, which are realized as helical springs. The first of these springs 4 is attached, by its first end, to the magnet 3, and by its second end to the cover 11. The second spring 4 is attached, by its first end, to the magnet 3, and by its second end to the support plate 7. The magnet 3 held by the two springs 4 can thus in each case oscillate back and forth in the vertical direction between the cover 11 and the support plate 7.

On the right side of the light guide 12, in the view of FIG. 1, a third oscillation system is provided with a movable magnet 3. This third oscillation system comprises, as restoring elements, two fixed magnets 14. The two fixed magnets 14 are immovably fastened, in the interior 18 of the trim strip, to a coil and magnet holder 15, in such a manner that they can exert a magnetic restoring force on the intermediately disposed magnet 3. Since the two magnets 14 are both disposed at the same level between the support plate 7 and the cover 11 in the interior 18, the movable magnet can oscillate back and fort in a horizontal direction between the two fixed magnets 14. The movable magnet 3 in this case is guided, in respect of its motion, by the coil and magnet holder 15.

Since the embodiment of FIG. 1 has oscillation systems oriented both in the horizontal and in the vertical direction, an electric current can be generated irrespective of the direction of the vehicle vibrations.

In order to convert the kinetic energy of the magnet 3 during the back and forth oscillation into an electric current, all oscillation systems respectively have at least one induction unit. An induction unit comprises, respectively, a coil body 2 having a plurality of windings.

The coil body 2 is disposed in such a manner that, during the oscillation motion of the magnet 3, an electric current is generated in the windings of the coil body by means of electromagnetic induction. For this purpose, the magnet 3 is usually designed as a permanent magnet. For the purpose of setting the resonant frequency of the oscillation system, the windings of the coil body 2 can each be switched into and out of circuit individually.

The electric current induced in the coil bodies 2 is conducted to an ultracapacitor 10. The ultracapacitor 10 has a flat structural form, and is disposed between the support plate 7 and the light guide 12. It serves, as an energy storage, to store the current induced in the coil bodies 2, such that electrical energy continues to be available even after stoppage of the vehicle.

The trim strip shown in FIG. 1 additionally has an acceleration sensor 17 disposed in the interior 18. The acceleration sensor 17 serves to determine the vibration frequencies of the vehicle. For this purpose, the acceleration data acquired by the acceleration sensor 17 are routed to an electronic device 8, in which a frequency analysis is performed and the current vibration frequencies of the vehicle are determined. Depending on the level of the determined vibration frequencies, more or fewer windings of the coil body 2 are switched into or out of circuit by the electronic device 8, which is a control unit. Depending on the number of windings of the coil body 2 that are switched into circuit during the oscillation motion of the magnet 3, a higher or lower resonant frequency of the oscillation system ensues, according to Lenz's law. By means of the acceleration sensor 17 and the switching into circuit of more or fewer windings of the coil body 2, the resonant frequency of the oscillation systems provided in the trim strip can thus be adjusted, by the electronic device 8, to a current oscillation frequency of the vehicle. The electric power generation can thereby be matched automatically to the vehicle type, the tires, the road condition (asphalt, gravel, snow, etc.), the charge state, etc.

Unlike the embodiment shown in FIG. 1, in each of the embodiments of FIGS. 2 and 3 there are only two oscillation systems, which each comprise a magnet 3 that is movable in the horizontal direction. The magnet 3 is disposed between two helical springs 4, and is held by respectively one end of these springs 4. The springs 4 are each attached, by their other end, to a spring holder 1 that is fixed in the interior 18. Whereas the spring-based oscillation systems in the case of the embodiment shown in FIG. 2 are both disposed on the same side of the light guide 12, in the case of the embodiment shown in FIG. 3 there is a respective horizontal, spring-based oscillation system provided on both sides, next to the light guide 12.

The embodiment shown in FIG. 4 differs from the embodiment of FIG. 1 in that, instead of the two vertical, spring-based oscillation systems, a single horizontal, magnet-based oscillation system is provided. Thus, here, disposed on both sides of the light guide 12 there are identically realized oscillation systems, each having a magnet 3, which is movable between two fixed magnets 14 and, moreover, encompassed by corresponding coil bodies 2.

Whereas the two horizontal, magnet-based oscillation systems in the case of the embodiment of FIG. 4 are disposed on both sides next to the light guide 12, in the case of the embodiment shown in FIG. 5 they are disposed on one side next to the light guide 12.

FIG. 6 shows a further embodiment, in which the inertial masses, i.e. the magnets 3, do not each oscillate translationally back and forth during the oscillating state, but execute a rotational motion (rotation direction 16). For this purpose, the magnets 3 each have the shape of a disk that lies flat in the horizontal plane of the trim strip 3. The magnets 3 in this case are each connected to a torsion spring, not visible in FIG. 6, that serves here as a restoring element. Here, also, a coil body 2 encompasses the magnet 3, at least partly, such that, upon a motion of the magnet 3, an electric current is induced in the coil body 2.

The embodiment shown in FIG. 6 additionally has a light sensor 19, in order to detect the opening state of the door and, in dependence thereon, to switch the lighting element 9 on or off. The use of a light sensor 19 is advantageous, in particular, if the electric power generating device is an entry strip. The light sensor 19, which is usually connected to the electronic device 8, could clearly also be provided in the case of the embodiments shown in FIGS. 1 to 5.

Illustrated in FIG. 7 are the x, y and z axes of a vehicle, the origin of the coordinate system formed by the x, y and z axes being disposed within the electric power generating device. The longitudinal axis 20 of the vehicle extends parallel to the x axis, along the direction of travel. The inertial masses 3, shown in FIGS. 1 to 5, of the horizontally oriented oscillation systems are preferably each movable along the x axis.

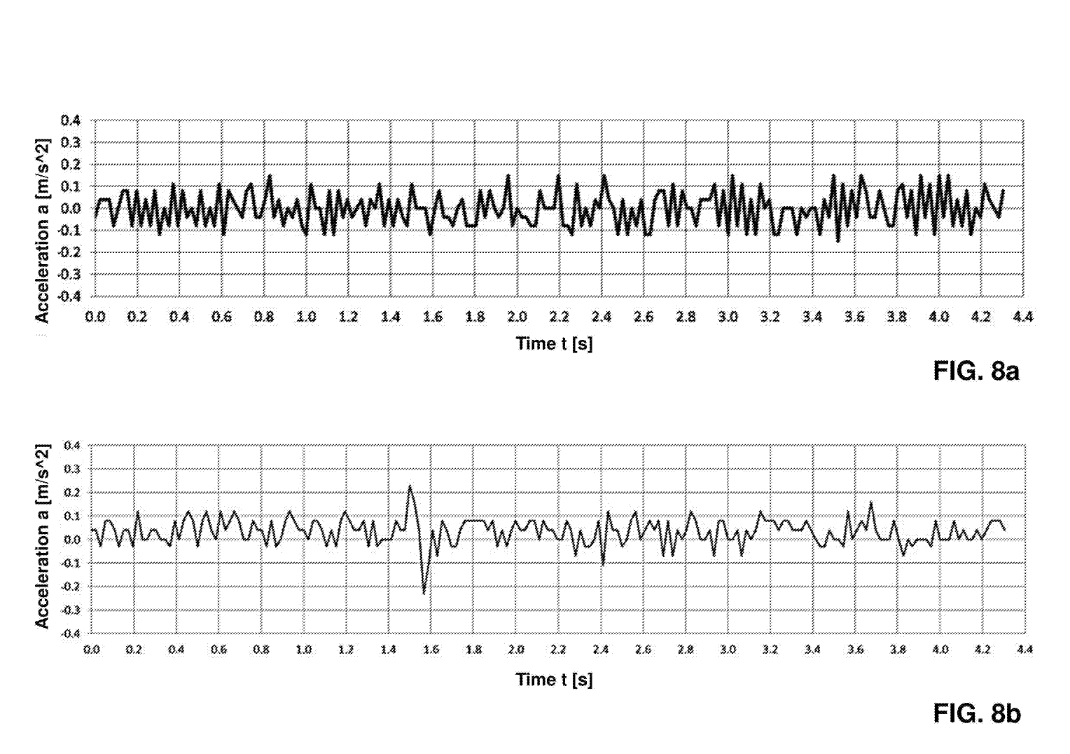

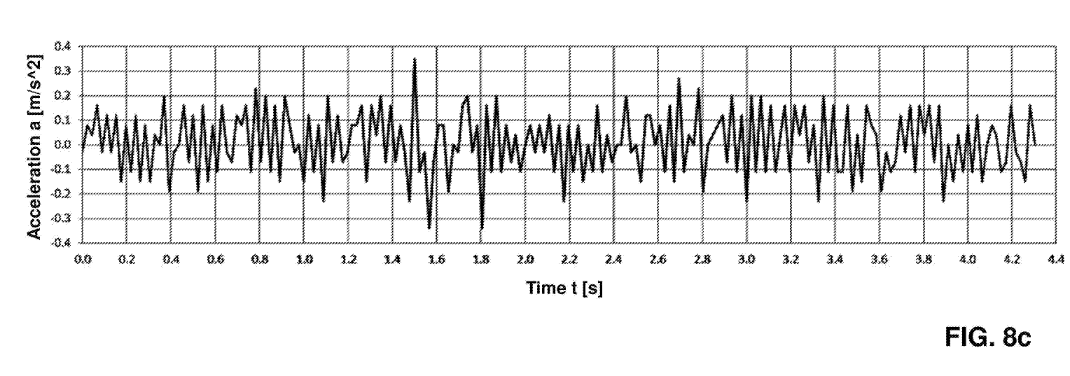

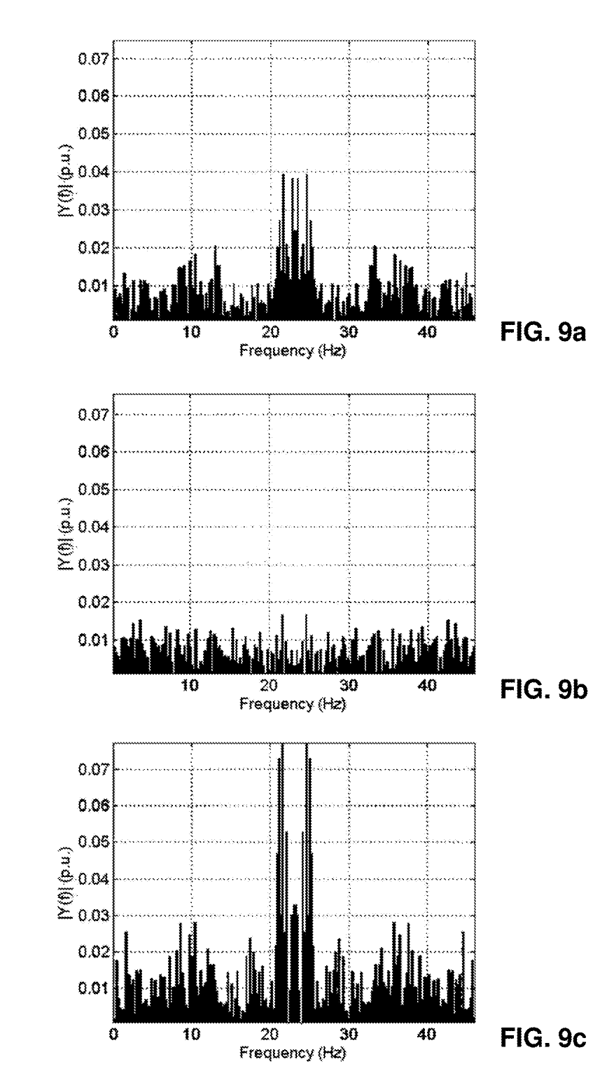

FIGS. 8a, 8b and 8c show the acceleration data of a vehicle determined by the acceleration sensor 17 in a trial over a certain period of time. With reference to FIG. 7, FIG. 8a represents the x component, FIG. 8b the y component, and FIG. 8c the z component of the acceleration caused by the vehicle vibrations. FIGS. 9a, 9b and 9c show the corresponding spectra in the frequency domain. The conversion of the data from the time domain to the frequency domain and vice versa is achieved by means of a Fourier transformation, which can be performed, in particular, by the electronic device 8. The Fourier transformation has long been known to persons skilled in the art. On the basis of these spectra, in the electronic device 8 one or more frequencies, in particular maximum frequencies, are selected, to which the respective resonant frequency of the oscillation systems 3, 4 or 3, 14 shown in FIGS. 1-6 is then adjusted.

Clearly, the present invention is not limited to the above-mentioned embodiments, but, rather, a multiplicity of modifications are possible. Thus, for example, the device need not necessarily have a light guide 12. For example, a lighting element could also be disposed behind each of the through-holes 13. The coil bodies 2 need not necessarily be disposed in such a manner that the movable magnets 3, in their oscillation motion, are at least partly encompassed by these coil bodies. During the oscillation, for example, the magnets 3 could also move perpendicularly back and forth in relation to the longitudinal directions of the coil bodies, in front of the latter. Instead of a coil body, it would also be possible to use one or more straight wires, in which an electric current is induced during the oscillation motion. Instead of being used in a trim strip, the electric power generating device, with the oscillation system and the induction unit, could be used in any other vehicle region, and used, for example, for interior or trunk illumination, for illuminating the dashboard or the vehicle registration, etc. A multiplicity of further modifications are possible.

LIST OF REFERENCES

| | |
|---|---|
| 1 | spring holder |
| 2 | coil body |
| 3 | magnet (movable) |
| 4 | spring |
| 5 | movement direction |
| 6 | free space |
| 7 | support plate |
| 8 | electronic device |
| 9 | lighting element |
| 10 | ultracapacitor |
| 11 | cover |
| 12 | light guide |
| 13 | through-hole |
| 14 | magnet (fixed) |
| 15 | coil and magnet holder |
| 16 | rotation direction |
| 17 | acceleration sensor |
| 18 | interior |
| 19 | light sensor |
| 20 | longitudinal axis |

1. An electric power generating, backlightable trim strip for a vehicle, having
an oscillation system having a movably disposed inertial mass and
an induction unit for inductively converting kinetic energy of the inertial mass into electrical energy;
at least one sensor for determining an oscillation frequency of the vehicle and
a control unit for adjusting the resonant frequency of the oscillation system to a determined oscillation frequency of the vehicle.

2. The backlightable trim strip as claimed in claim 1, wherein the sensor is an acceleration sensor.

3. The backlightable trim strip as claimed in claim 1, wherein the induction unit has at least one induction coil having a multiplicity of windings, wherein at least one winding can be switched into and out of circuit for the purpose of adjusting the resonant frequency of the oscillation system.

4. The backlightable trim strip as claimed in claim 1, having a housing, having an interior within which the oscillation system, the induction unit and the sensor are disposed.

5. The backlightable trim strip as claimed in claim 1, wherein the trim strip has an interior, in which the oscillation system, the induction unit and the sensor, and at least one lighting element, are disposed.

6. The backlightable trim strip as claimed in claim 5, wherein the interior is covered outwardly by a cover that is translucent to the lighting element, in particular has backlightable through-holes.

7. The backlightable trim strip as claimed in claim 1, which has a lighting element for the purpose of backlighting, and which additionally has a light sensor, in order to detect the opening state of a vehicle door and to switch the lighting element on or off in dependence on the detected opening state of the vehicle door.

8. The backlightable trim strip as claimed in , wherein the resonant frequency of the oscillation system is in the range of from 15 to 80 Hz.

9. The backlightable trim strip as claimed in claim 1, wherein the backlightable trim strip has at least one spring in order, upon the inertial mass moving out of its neutral position, to exert, as a restoring element, a restoring force on the inertial mass, in the direction of the neutral position.

10. The backlightable trim strip as claimed in claim 1, wherein the backlightable trim strip has at least one magnet in order, upon the inertial mass moving out of its neutral position, to exert, as a restoring element, a restoring force on the inertial mass, in the direction of the neutral position.

11. The backlightable trim strip as claimed in claim 1, additionally having an energy storage, in particular a capacitor storage, for storing the electrical energy generated by the induction unit.

12. The backlightable trim strip as claimed in claim 1, wherein the inertial mass has a permanent magnet.

13. A vehicle having a backlightable trim strip that comprises
an oscillation system having a movably disposed inertial mass; and
an induction unit for inductively converting kinetic energy of the inertial mass into electrical energy;
at least one sensor for determining an oscillation frequency of the vehicle; and
a control unit for adjusting the resonant frequency of the oscillation system to a determined oscillation frequency of the vehicle.

14. The vehicle as claimed in claim 13, wherein the backlightable trim is fixedly connected to the body of the vehicle.

15. The vehicle as claimed in claim 13, wherein the oscillation system of the backlightable trim strip, with regard to the direction of motion of the inertial mass when in the oscillating state, is disposed substantially parallel to the longitudinal axis of the vehicle.
